(19) United States
(12) Patent Application Publication
(10) Pub. No.: US 2025/0329403 A1
(43) Pub. Date: Oct. 23, 2025

(54) ENHANCEMENTS TO PROGRAMMING HALF-GOOD AND THIRD-GOOD BLOCKS IN THREE-DIMENSIONAL MEMORY

(71) Applicant: Micron Technology, Inc., Boise, ID (US)

(72) Inventors: Shyam Sunder Raghunathan, Singapore (SG); Waing Pyie Soe, Singapore (SG); Alex Sheng-Huang Lee, Meridian, ID (US)

(21) Appl. No.: 19/078,641

(22) Filed: Mar. 13, 2025

Related U.S. Application Data
(60) Provisional application No. 63/635,029, filed on Apr. 17, 2024.

(51) Int. Cl. G11C 29/12

(52) U.S. Cl. CPC G11C 29/12005; G11C 2029/1202

(57) ABSTRACT

A memory device includes a three-dimensional (3D) memory array comprising a plurality of blocks and control logic coupled to the 3D memory array. The control logic identifies a defective portion of a block of the plurality of blocks, wherein the defective portion is located above a non-defective portion of the block and causes the defective portion to be pre-programmed before programming the non-defective portion. While pre-programming the defective portion, the control logic causes a first voltage to be applied to a top plurality of wordlines of the defective portion and causes a second voltage to be applied to a bottom plurality of wordlines of the defective portion that are located below the top plurality of wordlines, wherein the second voltage is lower than the first voltage.

### CLAIM OF PRIORITY

The present application claims the benefit under 35 U.S.C. § 119(e) of U.S. Provisional Patent Application No. 63/635,029 filed Apr. 17, 2024, which is incorporated herein by this reference.

### TECHNICAL FIELD

Embodiments of the disclosure relate generally to memory sub-systems, and more specifically, enhancements to programming half-good and third-good blocks in three-dimensional (3D) memory.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system in accordance with some embodiments.

FIG. 1B is a block diagram of a memory device in communication with a memory sub-system controller of a memory sub-system, in accordance with some embodiments.

FIG. 2A is a schematic of portions of an array of memory cells as could be used in a memory of the type described with reference to FIG. 1B in accordance with some embodiments.

FIG. 2B is a schematic diagram illustrating a string of memory cells in a data block of a memory device in a memory sub-system in accordance with some embodiments.

FIG. 3A is a diagram illustrating a memory array of a bi-deck memory device, in accordance with some embodiments of the present disclosure.

FIG. 3B is a diagram illustrating a memory array of a multi-deck memory device, in accordance with some embodiments of the present disclosure.

FIG. 4A is a flow diagram of an example method of pre-programming a defective portion of a multi-deck memory device in accordance with some embodiments.

FIG. 4B is a flow diagram of an example method of pre-programming a defective portion of a multi-deck memory device in accordance with other embodiments.

FIG. 5 is a timing diagram for operation of a memory device during a seeding phase of a program operation, in accordance with some embodiments of the present disclosure.

FIG. 6 is a flow diagram of an example method of adjusting boost capability of a defective portion while programing a non-defective portion of a multi-deck memory device according to some embodiments.

FIG. 7 is a block diagram of an example computer system in which embodiments of the present disclosure can operate.

### DETAILED DESCRIPTION

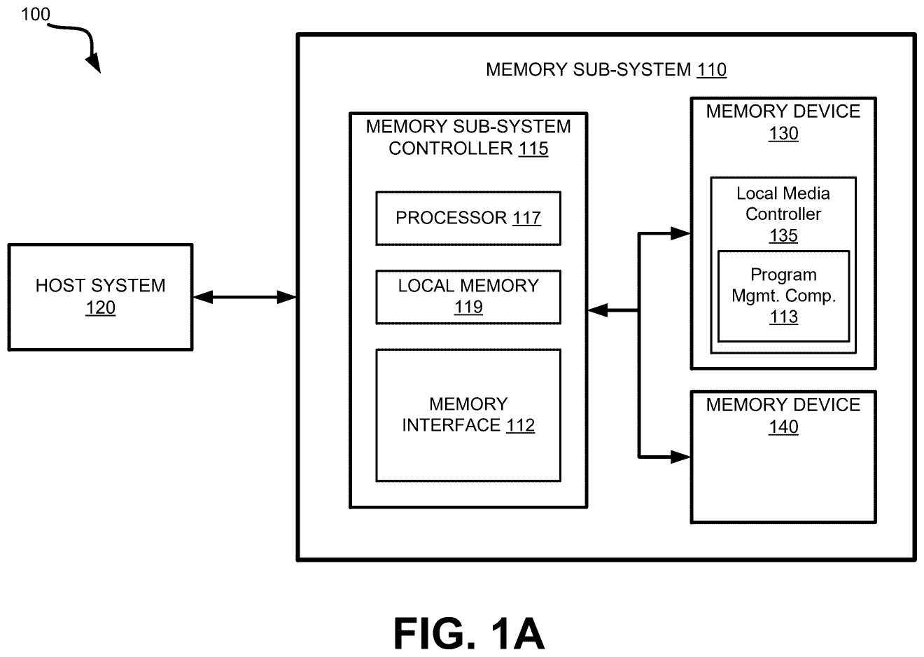

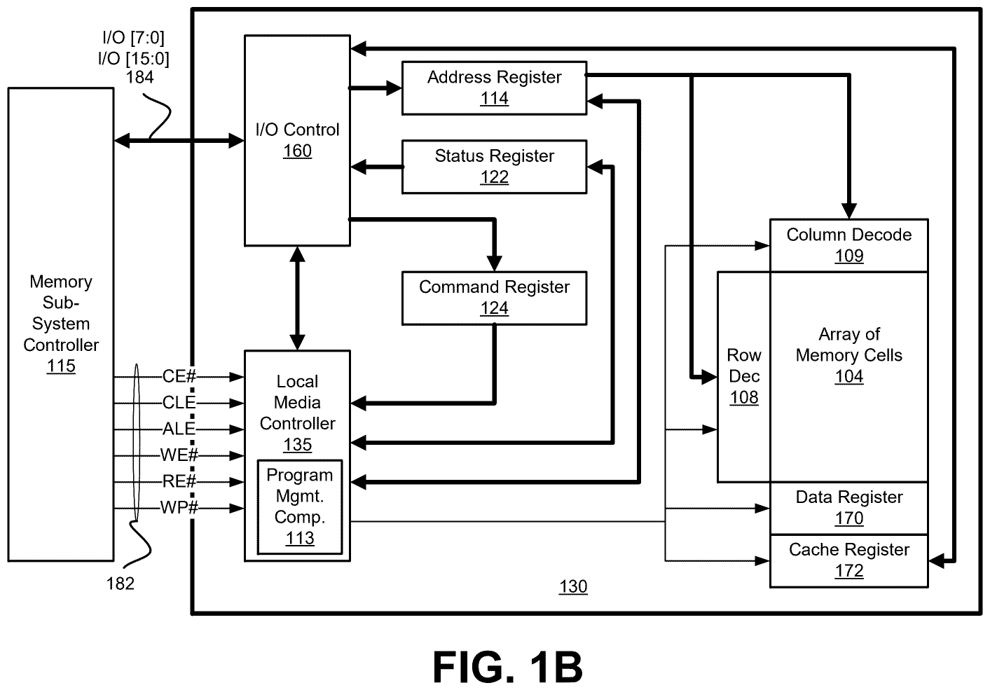

Aspects of the present disclosure are directed at enhancements to programming half-good and third-good blocks (HGB/TGB) in a 3D memory device of a memory sub-system according to some embodiments. A memory sub-system can be a storage device, a memory module, or a combination of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high-density, non-volatile memory devices where retention of data is desired when no power is supplied to the memory device. For example, NAND memory, such as 3D flash NAND memory, offers storage in the form of compact, high-density configurations. A non-volatile memory device is a package of one or more memory dies, each including one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1,” or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A data block hereinafter refers to a unit of the memory device used to store data and can include a group of memory cells, a wordline group, a wordline, or individual memory cells. Each data block can include a number of sub-blocks, where each sub-block is defined by a set of associated pillars (e.g., one or more vertical conductive traces) extending from a shared bitline. Memory pages (also referred to herein as “pages”) store one or more bits of binary data corresponding to data received from the host system. To achieve high density, a string of memory cells in a non-volatile memory device can be constructed to include a number of memory cells at least partially surround a pillar of channel material. The memory cells can be coupled to access lines, which are commonly referred to as “wordlines,” often fabricated in common with the memory cells, so as to form an array of strings in a block of memory. The compact nature of certain non-volatile memory devices, such as 3D flash NAND memory, means wordlines are common to many memory cells within a block of memory.

A desire for increased storage capacity in memory devices drives an expansion of block sizes, including an increase of the number of wordlines in each block. The presence of additional wordlines, however, presents certain challenges, including, for example, performance, and reliability penalties attributable to various inefficiencies, e.g., associated with garbage collection or other media management operations for the increased block size. As device sizes increase to accommodate an increase in number of wordlines, manufacturing of the memory devices also becomes more difficult due to the depth increase of etching required to make tall blocks of 3D memory. For example, the sheer sides of etched blocks are closer together at the bottom than at the top of device features, creating inconsistencies in structural dimensions and in device operation across depth of the device. Certain memory devices are thus divided into multiple segments, sometimes referred to as “decks,” so that width of etching can be more consistent despite the increase in depth. For example, a memory device could include an upper (or “top”) deck and a lower (or “bottom”) deck, each including a respective set of wordlines from the block.

When programming 3D memory, memory cells coupled to wordlines can be programmed in a memory string from a drain end of the memory string to a source end of the memory string, e.g., from top to bottom of each memory string. At least one reason for this “drain-to-source” (or D2S) programming order in a regular full block case is because programming in this order reduces the threshold voltage (Vt) shift due to cell-to-cell coupling, e.g., the Vt shift of WLn after WLn+1 is programmed is smaller if WLn+1 is below WLn instead of being above WLn. This reason may only be applicable for programming order within a deck, as being related to the immediate neighbor wordline, for example.

Also when programming 3D memory, there are reasons for programming a top bad (e.g., defective) deck before programming a bottom good deck. One reason for this includes that there is worse charge loss on the bottom deck cells (especially on the first few wordlines) if the top deck is in erased state. Another reason includes that the top deck being in erased state modifies the programming boosted potential seen on program inhibited channels, and makes programming boosted potential inconsistent with the regular full block programming boost level. The modified boost potential is a program disturb risk.

Other phenomena can affect the charge of a memory cell, including slow charge loss (SCL). For example, SCL represents the change to the threshold voltage (VT) of the memory cell with respect to time as the electric charge of the cell degrades (e.g., as the voltage shifts). The threshold voltage shift from SCL can be referred to as “temporal voltage shift,” since the degrading electric charge causes the voltage distributions to shift along the voltage axis towards lower voltage levels as a function of time. The threshold voltage changes rapidly at first (e.g., immediately after the memory cell was programmed), and then slows down in an approximately logarithmic linear fashion with respect to the time elapsed since the cell programming event. The programmed state of adjacent wordlines can also affect the charge of the memory cell. For example, due to the close proximity of the memory cells in adjacent wordlines, the charge of memory cells in a wordline can shift up over time when memory cells in an adjacent wordline have been programmed with a high charge. The temporal voltage shift can further be impacted by number of program-erase (or PE) cycles as well as temperature. For example, in the context of multi-deck 3D memory, an erased defective top deck can cause worse data retention due to SCL on the good bottom deck.

Defects in memory devices can impact device performance, reliability, and capacity, and by separating memory devices into multiple decks, new potential points for defects can be introduced. For example, due to various factors, such as a manufacturing error, the top deck of a block can be functional while the bottom deck is defective, or the bottom deck of the block can be functional while the top deck is defective. Some systems can partially recover these “half good” blocks (i.e., blocks with either a non-defective top deck or a non-defective bottom deck). In a memory device that is programmed using a top-down programming algorithm (i.e., where the top deck of the block is programmed before the bottom deck of the block), there is no need to consider preventing read disturb or other potential voltage shift phenomena, and thus non-defective top decks can be programmed by halting the programming algorithm when a defective bottom deck is encountered. In some instances, defective bottom decks can subsequently be treated (e.g., for example, programmed with a specific voltage pattern) to have a minimal effect on the charges of the non-defective top deck (i.e., the stored data) by the top-down programming algorithm.

However, this same process does not work in the reverse, i.e., where the top deck of the block is defective, and the bottom deck of the block is non-defective. For example, as the bottom deck is independently accessible for memory access operations, the non-defective bottom deck can be programmed independently (e.g., similar to programming the non-defective top deck in the previous example). But, in practice, if the defective top deck remains in an erased state, there are worse charge loss and program disturb risks on the bottom deck. As a result, even systems that partially recover blocks with non-defective top decks can mark blocks with a defective top deck and non-defective bottom deck as bad blocks and remove the blocks from accessible memory because of theses programming issues. Thus, instead of simply losing functionality of fully defective blocks (e.g., blocks with defective top decks and defective bottom decks), the functionality of blocks with non-defective bottom decks can also be lost.

Aspects of the present disclosure address the above and other deficiencies by implementing a half-good (and/or third-good) block handling technique to pre-program defective decks on a multi-deck memory device while also making adjustments to such pre-programming that improve lifetime, power expenditure, and performance of the memory device. Thus, for example, some pre-programming approaches can endeavor to match a state that a regular full block would see with its top deck in programmed state before the bottom deck is also programmed, e.g., where the bottom deck is part of a half good bock (HGB). The pre-programming may be performed to defective top decks before programming non-defective bottom decks such that the top-down programming algorithm may still be followed to minimize program disturb and data retention affects to the non-defective bottom decks. Herein, in the context of the present disclosure, a non-defective portion of a block may be understood as corresponding to one or more bottom good decks that are closest to the substrate of 3D memory device that has been etched with multiple decks. Further, a defective portion of a block may be understood as corresponding to one or more top good decks that are located above the non-defective portion, e.g., such that the non-defective portion is located between the substrate and the defective portion.

In order to program the non-defective portion while minimizing the negative programming effects, the 3D memory device can pre-program a voltage pattern to the defective portions (e.g., one or more top bad decks located above a non-defective bottom deck). The voltage pattern can be a certain voltage distribution, voltage level, etc., and can be selected based on physical characteristics of the memory device. The voltage pattern can be selected as a pattern which when programmed to a defective deck, can cause minimal voltage shift to an adjacent non-defective deck. Pre-programming can be performed during the memory manufacturing stage, or in conjunction with memory access operations such as an erase operation, program operation, etc. Due to various voltage shift effects described above (e.g., SCL, etc.), and/or effects such as program disturb, the voltage pattern programmed to the defective decks can change over time. The memory device can detect these changes to the threshold voltage of the defective deck(s) and re-program the defective deck(s) with the pre-programming voltage pattern. The defective decks can be pre-programmed at a time or in a way to minimize program disturb effects on data stored on lower decks (e.g., a bottom deck).

The pre-programming voltage pattern can be programmed to the defective portion of the block any time before a programming operation is performed. This includes, for example, during manufacture of the memory device (e.g., as an “out-going pattern” from a manufacturing environment), immediately preceding a program operation, or after an erase operation. Performing the pre-programming operation during manufacture of the memory device can reduce the performance impact on subsequent memory access operations performed on the memory device in comparison to the other two indicated options. Performing the pre-programming operation immediately preceding a program operation can allow the controller to precisely control the read window budget (RWB) of the subsequently programmed data, but at the expense of an impact to the performance of the program operation, because of the increased latency from an extra programming operation, e.g., the pre-programming operation on the defective portion of the block. Performing the pre-programming operation after an erase operation does not negatively impact the performance of a programming operation, but does negatively impact the overall memory device performance by negatively impacting the performance of the erase operation (e.g., by adding additional latency to the erase operation).

Because pre-programming during on-going memory operations impacts the PE cycles, and thus lifetime of the memory device, as well as power expended and performance, for reasons just discussed, enhancements may be employed singularly or in the aggregate in relation to HGB/TGB programming to improve lifetime, power expenditure, and performance. These improvements can be particularly related to pre-programming a defective portion of a block that is located at one or more top decks. In some embodiments, which will be discussed in more detail, pre-programming the defective portion may occur at different speeds due to the varying diameter etching of each deck. This speed difference may be primarily due to the memory cells at the bottom of the top bad deck being smaller, and thus being programmed faster, than the memory cells located towards the top of the top bad deck where the memory cells are relatively larger than the bottom memory cells. Thus, when programming the entire bad deck with the same voltage in a single pulse (to save time and power), the top memory cells may be programmed to higher voltages than the bottom memory cells of the defective portion, causing unwanted stress due to voltage differential along pillars of memory cell strings.

Thus, in at least one embodiment, the 3D memory device (e.g., control logic of the memory device) identifies a defective portion of a block of a plurality of blocks of a 3D memory device. The defective portion may be located above a non-defective portion of the block, as was discussed. The memory device may further cause the defective portion to be pre-programmed before programming the non-defective portion. Further, while pre-programming the defective portion, the memory device may cause a first voltage to be applied to a top plurality of wordlines of the defective portion and may cause a second voltage to be applied to a bottom plurality of wordlines of the defective portion that are located below the top plurality of wordlines. In embodiments, the second voltage is lower than the first voltage, which is meant to even out the speed of programming between the top and bottom sets of wordlines of the defective portion so that threshold voltages have less variation. Here, the terms “top” and “bottom” may be understood in the same context and direction as was explained with reference to the defective and non-defective portions, e.g., the bottom being nearest the substrate and thus, in this case, nearest to the non-defective portion (or good bottom deck).

Advantages of the present disclosure include, but are not limited to, improved performance in the memory device. In the manner described herein, a drain-to-source (i.e., top to bottom) programming algorithm (e.g., a top-down programming algorithm) can be used effectively in a multi-deck memory device to program bottom decks when top deck(s) are defective. The voltage distributions of the non-defective bottom decks can be minimally affected by the voltage pattern programmed to the defective top deck(s). In one embodiment, a reliably programmed bottom deck below a defective top deck can improve memory device performance by reducing losses due to defective portions of the memory device. Further, by applying the disclosed enhancements primarily to pre-programming the defective portions (e.g., of a bad top deck), HGB/TGB programming techniques may be performed while also increasing lifetime of the memory device, reducing power consumption, and improving overall performance of the memory device, e.g., improved program and/or erase operations that involve pre-programming.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

In one embodiment, the memory sub-system 110 includes a memory interface component 112. Memory interface component 112 is responsible for handling interactions of memory sub-system controller 115 with the memory devices of memory sub-system 110, such as memory device 130. For example, memory interface component 112 can send memory access commands corresponding to requests received from host system 120 to memory device 130, such as program commands, read commands, or other commands. In addition, memory interface component 112 can receive data from memory device 130, such as data retrieved in response to a read command or a confirmation that a program command was successfully performed. In some embodiments, the memory sub-system controller 115 includes at least a portion of the memory interface 112. For example, the memory sub-system controller 115 can include a processor 117 (processing device) configured to execute instructions stored in local memory 119 for performing the operations described herein. In some embodiments, the memory interface component 112 is part of the host system 110, an application, or an operating system.

In one embodiment, memory device 130 includes a memory device program management component 113 that can oversee, control, and/or manage data access operations, such as program operations, performed on a non-volatile memory device, such as memory device 130, of memory sub-system 110. In one embodiment, local media controller 135 includes at least a portion of program management component 113 and is configured to perform the functionality described herein, particularly in relation to pre-programming a defective portion of a block (e.g., one or more bad top decks) or adjusting boost levels in the defective portion while programming a non-defective portion (e.g., one or more good bottom decks) coupled to the same pillar. In such an embodiment, program management component 113 can be implemented using hardware or as firmware, stored on memory device 130, executed by the control logic (e.g., program management component 113) to perform the operations described herein. In some embodiments, one or more operations performed by the program management component 113 are performed by the memory sub-system controller 115 or processing device that is external to but works in connection with the memory device 130.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bitline). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses. In one embodiment, local media controller 135 includes program management component 113, which can implement the HGB/TGB enhancement techniques during program operations (and some erase and read operations) on a multi-deck memory device, such as memory device 130.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 182. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 182 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 184 and outputs data to the memory sub-system controller 115 over I/O bus 184.

For example, the commands may be received over input/output (I/O) pins [7:0] of I/O bus 184 at I/O control circuitry 160 and may then be written into command register 124. The addresses may be received over input/output (I/O) pins [7:0] of I/O bus 184 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B.

Additionally, while specific I/O pins are described in accordance with popular conventions for receipt and output of the various signals, it is noted that other combinations or numbers of I/O pins (or other I/O node structures) may be used in the various embodiments.

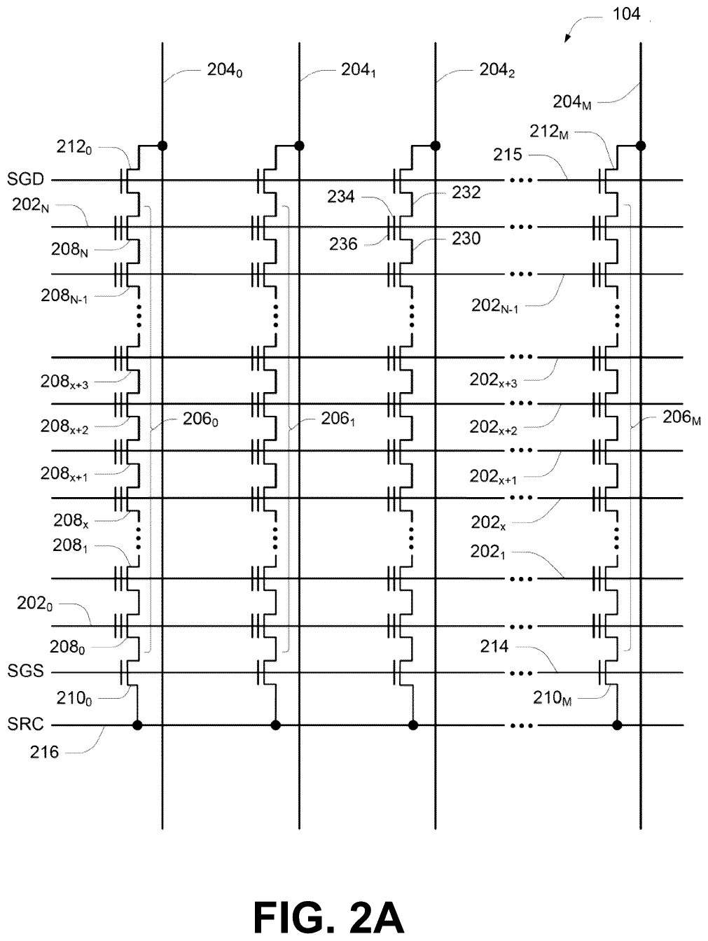

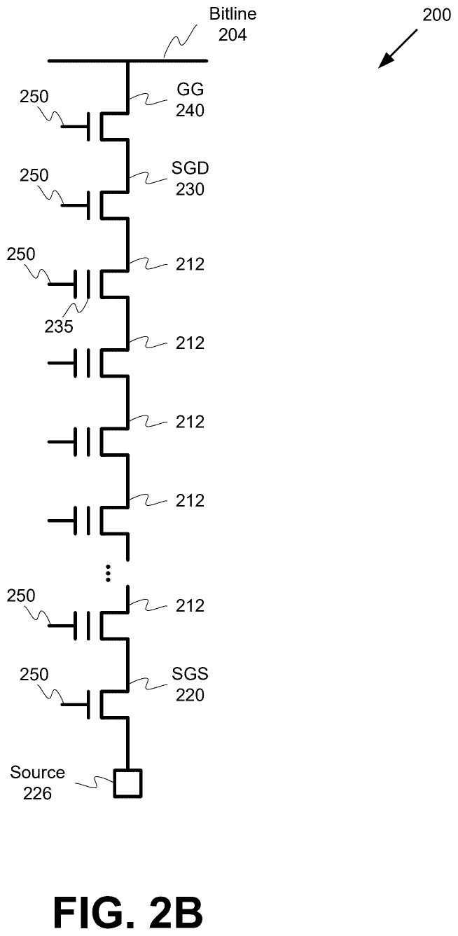

FIG. 2A is a schematic of portions of an array of memory cells 104, such as a NAND memory array, as could be used in a memory of the type described with reference to FIG. 1B according to an embodiment. Memory array 104 includes access lines, such as wordlines 202₀ to 202_{N}, and data lines, such as bitlines 204₀ to 204_{M}. The wordlines 202 can be connected to global access lines (e.g., global wordlines), not shown in FIG. 2A, in a many-to-one relationship. For some embodiments, memory array 104 can be formed over a semiconductor that, for example, can be conductively doped to have a conductivity type, such as a p-type conductivity, e.g., to form a p-well, or an n-type conductivity, e.g., to form an n-well.

Memory array 104 can be arranged in rows (each corresponding to a wordline 202) and columns (each corresponding to a bitline 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bitline 204 for the corresponding NAND string 206. For example, the drain of select gate 212₀ can be connected to the bitline 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bitline 204. A control gate of each select gate 212 can be connected to select line 215.

The memory array 104 in FIG. 2A can be a quasi-two-dimensional memory array and can have a generally planar structure, e.g., where the common source 216, NAND strings 206 and bitlines 204 extend in substantially parallel planes. Alternatively, the memory array 104 in FIG. 2A can be a three-dimensional memory array, e.g., where NAND strings 206 can extend substantially perpendicular to a plane containing the common source 216 and to a plane containing the bitlines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bitlines 204 (e.g., bitlines 204₀, 204₂, 204₄, etc.) can be one physical page of the memory cells 208 (e.g., even memory cells) while memory cells 208 commonly connected to wordline 202_{N} and selectively connected to odd bitlines 204 (e.g., bitlines 204₁, 204₃, 204₅, etc.) can be another physical page of the memory cells 208 (e.g., odd memory cells).

Although bitlines 204₃-204₅ are not explicitly depicted in FIG. 2A, it is apparent from the figure that the bitlines 204 of the array of memory cells 104 can be numbered consecutively from bitline 204₀ to bitline 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is a schematic diagram illustrating a string 200 of memory cells in a data block of a memory device in a memory sub-system in accordance with some embodiments. In one embodiment, the string 200 is representative of one portion of memory device 130, such as from array of memory cells 104, as shown in FIG. 2A. The string 200 includes a number of memory cells 212 (i.e., charge storage devices), such as up to 32 memory cells (or more) in some embodiments. The string 200 includes a source-side select transistor known as a source select gate 220 (SGS) (typically an n-channel transistor) coupled between a memory cell 212 at one end of the string 200 and a common source 226. The common source 226 may include, for example, a commonly doped semiconductor material and/or other conductive material. At the other end of the string 200, a drain-side select transistor called a drain select gate 230 (SGD) (typically an n-channel transistor) and a gate-induced drain leakage (GIDL) generator 240 (GG) (typically an n-channel transistor) are coupled between one of the memory cells 212 and a data line, which is commonly referred to in the art as a bitline 204. The common source 226 can be coupled to a reference voltage (e.g., ground voltage or simply “ground” [Gnd]) or a voltage source (e.g., a charge pump circuit or power supply which may be selectively configured to a particular voltage suitable for optimizing a programming operation, for example).

Each memory cell 212 may include, for example, a floating gate transistor or a charge trap transistor and may comprise a single level memory cell or a multilevel memory cell. The floating gate may be referred to as a charge storage structure 235. The memory cells 212, the source select gate 220, the drain select gate 230, and the GIDL generator 240 can be controlled by signals on their respective control gates 250.

The control signals can be applied by program management component 113, or at the direction of program management component 113, to select lines (not shown) to select strings, or to access lines (not shown) to select memory cells 212, for example. In some cases, the control gates can form a portion of the select lines (for select devices) or access lines (for cells). The drain select gate 230 receives a voltage that can cause the drain select gate 230 to select or deselect the string 200. In one embodiment, each respective control gate 250 is connected to a separate wordline (i.e., access line), such that each device or memory cell can be separately controlled. The string 200 can be one of multiple strings of memory cells in a block of memory cells in memory device 130. In one embodiment, wherein memory device 130 is a multi-deck memory device, each of the multiple memory strings can span two or more decks (e.g., a top deck, a bottom deck, and optionally a middle deck), such that certain memory cells 212 in the string 200 are part of the top deck and certain memory cells 212 are part of the bottom deck. For example, when multiple strings of memory cells are present, each memory cell 212 in string 200 may be connected to a corresponding shared wordline, to which a corresponding memory cell in each of the multiple strings is also connected. As such, if a selected memory cell in one of those multiple strings is being programmed, a corresponding unselected memory cell 212 in another string which is connected to the same wordline as the selected cell can be subjected to the same programming voltage, potentially leading to program disturb effects.

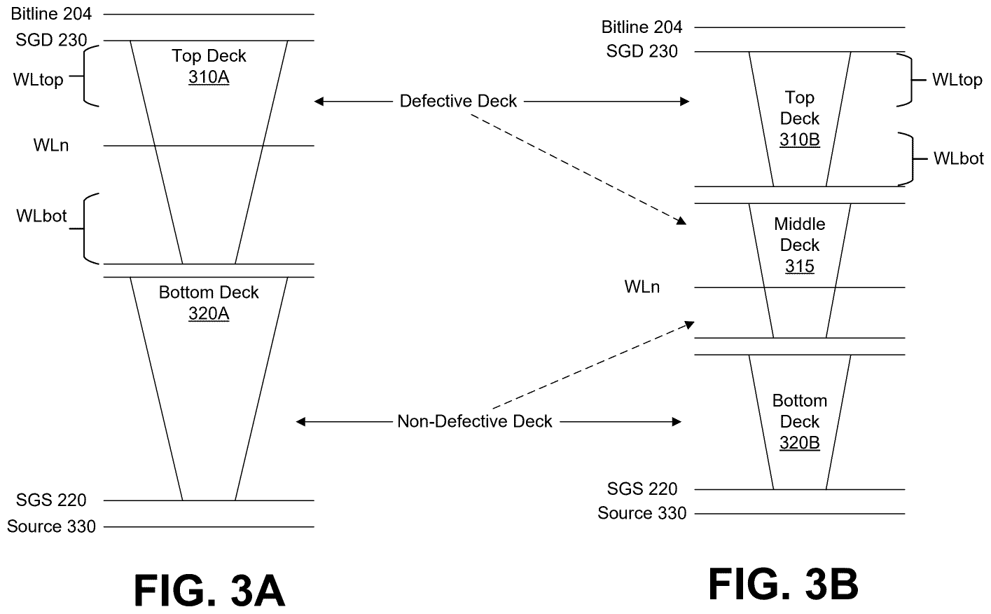

FIG. 3A is a diagram illustrating a memory array of a bi-deck memory device, in accordance with some embodiments, e.g., half-good block (HGB) programming. FIG. 3B is a diagram illustrating a memory array of a multi-deck memory device, in accordance with some embodiments, e.g., third-good block (TGB) programming. Although only two decks (i.e., a top deck 310A and a bottom deck 320A) are illustrated in FIG. 3A, it should be appreciated that certain memory devices can include more than two decks (e.g., three decks, four decks, and the like). For example, as shown in FIG. 3B, the memory array can include a top deck 310B, a middle deck 315, and a bottom deck 320B. In some embodiments, each deck includes a corresponding set of wordlines that are coupled to memory cells arranged in memory strings, such as string 200. In one embodiment, the top deck 310B is arranged vertically above the middle deck 315, which is arranged vertically above the bottom deck 320B, such that the memory strings can extend from a drain (e.g., bitline 204 accessible via SGD 230) adjacent to the top deck 310B, through the middle deck 315, to a source (e.g., source 330 accessible via SGS 220) adjacent to the bottom deck 320B of the memory array.

In other embodiments, there can be some other number or arrangement of decks in the memory device 130. In one embodiment, the program operation is a drain-to-source (D2S) program operation that proceeds wordline by wordline from the drain to the source within each deck. Accordingly, when the memory cells associated with a selected wordline (e.g., WLn) is being programmed, the memory cells associated with wordlines in the same deck and located above the selected wordline (i.e., closer to the SGD 230) will have already been programmed, while the memory cells associated with wordlines located in the same deck and below the selected wordline (i.e., closer to the SGS 220) will not yet have been programmed. Further, according to D2S programming, the programming may also not skip programming any intervening pages. For example, if a page of data is located along a wordline (WL) that is considered defective (e.g., has a short to another WL or other defect), this page may be programmed with a data pattern or some other dummy data. Thus, such memory devices with more than two decks may utilize a similar D2S programming algorithm and thus, face similar challenges as memory devices with two decks.

With additional reference to FIGS. 3A-3B, the embodiments referenced herein are described mostly in relation to a defective portion of a block that corresponds to the top deck 310A or 310B, when defective, and for TGB embodiments, the middle deck 315 can also be non-defective (denoted by the dashed arrow from the “non-defective deck”). In alternative TGB embodiments, however, the defective portion may also include the middle deck 315 when just the bottom deck 320B is considered non-defective (denoted by the dashed arrow from the “defective deck”). As was discussed, in the context of the present disclosure, a non-defective portion of a block may be understood as corresponding to one or more bottom good decks that are closest to the substrate of 3D memory device that has been etched with multiple decks. Further, a defective portion of a block may be understood as corresponding to one or more top good decks that are located above the non-defective portion, e.g., such that the non-defective portion is located between the substrate and the defective portion.

In some embodiments, as mentioned, pre-programming the defective portion may occur at different speeds due to the cone-shaped etching of each deck, also referred to as “pre-programming speed.” This speed difference may be primarily due to the memory cells at the bottom of the defective portion being smaller, and thus being programmed faster, than the memory cells located towards the top of the defective portion where the memory cells are relatively larger. Thus, without intervention, the top memory cells may be programmed to lower threshold voltages (because they are programed slower over the same time) than the bottom memory cells of the defective portion, causing unwanted stress due to voltage differential along pillars of memory cell strings of the memory device 130. For example, in some embodiments, a limit may be placed on voltage differential to some reasonable, yet small voltage, e.g., 1.0V, 1.5V, 1.8V, or the like, to reduce the stress along pillars of the 3D memory device.

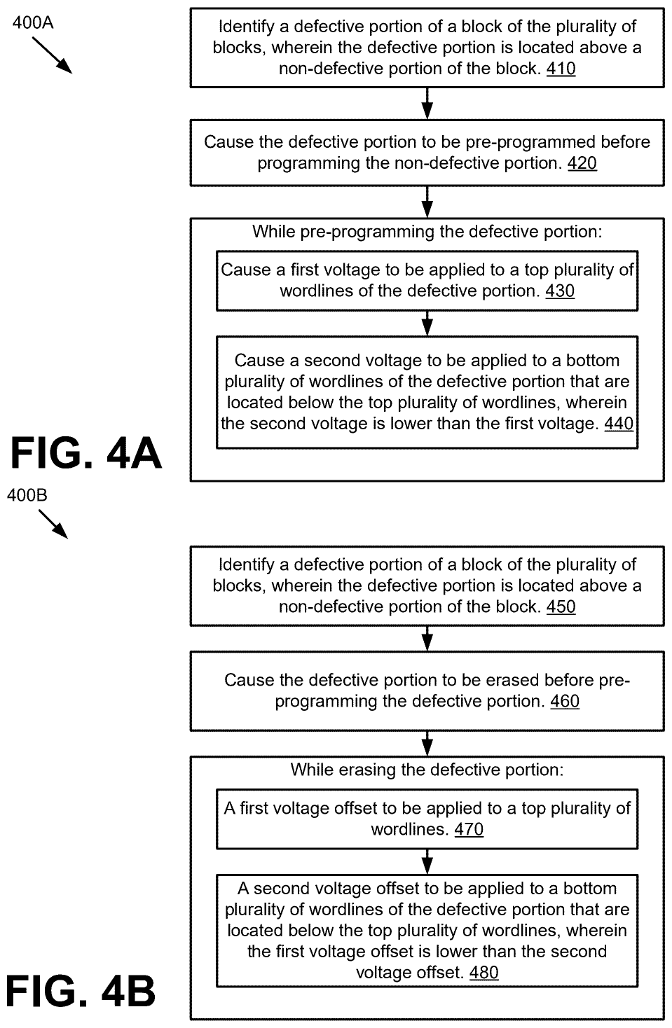

FIG. 4A is a flow diagram of an example method 400A of pre-programming a defective portion of a multi-deck memory device in accordance with some embodiments. The method 400A can be performed by control logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400A is performed by program management component 113 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 410, a defective portion of a block is identified. For example, the control logic (e.g., program management component 113) identifies a defective portion of a block of a plurality of blocks of the memory device 130. In embodiments, the defective portion is located above a non-defective portion of the block.

At operation 420, a defective portion is pre-programmed. For example, the control logic causes the defective portion to be pre-programmed before programming the non-defective portion. As discussed, this pre-programming may be performed during manufacture, or later either as part of (e.g., at the end of) an erase operation of the defective portion, or as a separate pre-programming operation after the erase operation has been performed. In varying embodiments, the control logic may employ either a single pulse or two pulses to perform the pre-programming. In some embodiments, the control logic causes to be supplied, from two voltage sources, a first voltage and a second voltage in a single pulse. In other embodiments, the control logic causes to be supplied, from a single voltage source, the first voltage in a first pulse and the second voltage in a second pulse.

At operation 430, a first voltage is applied to top wordlines of the defective portion. For example, while pre-programming the defective portion, the control logic causes a first voltage to be applied to a top plurality of wordlines of the defective portion, illustrated as WLtop in FIGS. 3A-3B.

At operation 440, a second voltage is applied to bottom wordlines of the defective portion. For example, while pre-programming the defective portion, the control logic causes a second voltage to be applied to a bottom plurality of wordlines of the defective portion that are located below the top plurality of wordlines, e.g., and are illustrated as WLbot in FIGS. 3A-3B. In embodiments, the second voltage is lower than the first voltage, which is meant to even out the speed of programming between the top and bottom sets of wordlines of the defective portion so that threshold voltages have less variation. In varying embodiments, the top plurality of wordlines (WLtop) and the bottom plurality of wordlines (WLbot) are illustrated as exemplary and can be any plurality of WLs located in the top half and the bottom half of the defective portion (e.g., top deck 310A or 310B, to include possibly also the middle deck 315, if defective). These top plurality of WLs and bottom plurality of WLs may encompass up to and including all the WLs in the top half and the bottom half of the defective portion, respectively.

In some embodiments, as a continuation of the method 400A, the control logic may also identify one or more wordlines of the defective portion that are defective, e.g., that are shorted or damaged in a way that each identified WL does not function properly. Conductivity tests, operational tests, and the like, can be performed to identify such WLs. While pre-programming the defective portion, these defective wordlines may be skipped from being pre-programmed. For example, the control logic may cause a voltage driver of the one or more wordlines to be turned off or routing the one or more wordlines to a pass voltage. Skipping pre-programming defective WLs (which would not be properly programmed anyway) may increase lifetime of the memory device 130 by reducing cycling on defective WLs. Further, skipping defective WLs in this way may also conserve power and program time (Tprog), e.g., faster pre-program ramp and pulse for fewer number of WLs being programmed.

Further, in some embodiments, the control logic may also reduce the pass voltage compared to a pass voltage used on unprogrammed wordlines of the non-defective portion, e.g., to achieve a target resistance during program verify, which will be discussed in more detail later. In various embodiments, the amount of pass voltage reduction may vary, e.g., between 25% to more than 50% reduction, depending on target resistance and current threshold voltage (Vt) levels. Reducing the pass voltage on the one or more skipped WLs may also reduce power consumption.

FIG. 4B is a flow diagram of an example method 400B of pre-programming a defective portion of a multi-deck memory device in accordance with other embodiments. The method 400B can be performed by control logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400B is performed by program management component 113 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

In some embodiments, when performing an erase operation on the defective portion, e.g., before pre-programming the defective portion, the memory cells located towards the top of the defective portion are larger, and thus are erased more slowly than the memory cells located towards the bottom of the defective portion. Typically a voltage of zero volts is applied to all WLs to erase a block. Instead, similar to what was described with reference to FIG. 4A (with different program voltages applied to different pluralities of WLs), here, a voltage offset may be applied differently to different pluralities of WLs depending on where the WLs are located. By applying such voltage offsets (see below operations), a voltage debias for the erase operation may be lessened and reduce stress on the defective portion of the block. Residual charge may remain in some (or most) of the memory cells due to such voltage offsets, but this may be acceptable because the pre-programming operation may take this into consideration and may just be programming dummy data that is not expected to be read out and used.

At operation 450, a defective portion of a block is identified. For example, the control logic (e.g., program management component 113) identifies a defective portion of a block of a plurality of blocks of the memory device 130. In embodiments, the defective portion is located above a non-defective portion of the block.

At operation 460, the defective portion is pre-programmed. For example, the control logic causes the defective portion to be erased before pre-programming the defective portion.

At operation 470, a first voltage offset is applied to top wordlines of the defective portion. For example, the control logic causes, while erasing the defective portion, a first voltage offset to be applied to a top plurality of wordlines.

At operation 480, a second voltage offset is applied to bottom wordlines of the defective portion. For example, the control logic causes, while erasing the defective portion, a second voltage offset to be applied to a bottom plurality of wordlines of the defective portion that are located below the top plurality of wordlines. In embodiments, the first voltage offset is lower than the second voltage offset. In this way, the lower first voltage offset at the top WLs compared to the second voltage offset at the bottom WLs provides an offset in erase debias, causing the top plurality of wordlines to be erased faster, e.g., to catch up speed of erase to being closer to that of the bottom plurality of wordlines. The result of this approach is to reduce erase stress on the HGB bad deck(s), e.g., the defective portion(s), increasing lifetime of the memory device 130.

With additional reference to FIGS. 3A-3B, the control logic may dynamically control pre-programming the defective portion(s) (e.g., of bad top or middle decks) through cycling and temperature to reduce energy consumption, improve erase time, and increase lifetime of the memory device 130. For example, every time a block is erased that includes a good bottom deck (herein, a non-defective portion), the control logic may direct a pre-program be performed on the defective portion of the top (and/or middle) deck(s). This pre-program operation may be hidden at the end of the erase operation, just discussed with reference to FIG. 4B, or as a separate program operation before programming the non-defective bottom deck(s).

In some embodiments, the control logic causes a pre-program verify operation to be performed on the defective portion to minimize a threshold voltage of programmed cells of the defective portion. This program verify operation may seek to ensure correct threshold voltages (and thus resistances) of the programmed memory cells of the defective portion across PE cycling and temperature. If the program verify operation is not successful, the control logic may direct further pre-programming until programming the memory cells to a target program verify voltage. The dynamic control of the pre-programming may further be adjusted in terms of timing, e.g., how long of a program pulse to reach the current threshold voltage. In some embodiments, the control logic consults a lookup table to determine a target threshold voltage (Vt) for the memory cells of the entire defective portion and/or of particular set of wordlines. Other adjustments may also be made dynamically, such as the program verify voltage level, number of skipped WLs, and the like.

In at least some embodiments, the control logic may further dynamically adjust a voltage of a pre-program pulse during the pre-programming of the defective portion to target the minimized threshold voltage (Vt-min) and to ensure pre-programming of the defective portion completes in a single pulse. For example, the target threshold voltage may be based on a number of program-erase cycles (or PE cycles) of the defective portion and/or on a current temperature of the 3D memory array. If performed accurately, these dynamic adjustments may obviate the need for a program verify operation of the defective portion, and thus save on program time.

More particularly, the control logic can increase the pre-program voltage with number of PE cycles. In embodiments, the control logic consults a lookup table so when the memory cells reach certain threshold voltages, the control logic triggers an incremental increase in pre-program voltage. The PE cycles may typically be tracked within the controller 115, but the program management component 113 of the local media controller 135 on-board of the memory device 130 can receive the PE cycles information from the controller 115 and perform the lookup table access to determine what incremental increases in pre-program voltage should be applied.

Further, in some embodiments, the control logic increases the pre-program voltage with a decrease in temperature or decreases the pre-program voltage with an increase in temperature. The temperature of the 3D NAND array may be tracked within the memory device 130 and the control logic can also use lookup table for tracking incremental changes in the pre-program voltage based on this tracked temperature.

TABLE 1

| Pre-Program Voltage (V) | # PE Cycles | Temperature (° C.) |
|---|---|---|
| X | 1 | 90 |
| X + Y | 1 | −40 |
| X + Z | 5000 | 90 |
| X + Y + Z | 5000 | −40 |

Table 1 illustrates some examples of impacts of PE cycles and temperature on pre-program voltage only for purposes of explanation. One of skill in the art would recognize that ability to linearly interpolate between values and build a lookup table to provide any level of granularity sought between pre-program voltage and PE cycles or between pre-program voltage and temperature. For example, if X is equal to 14V, Y is equal to 1V, and Z is equal to −2V, the pre-program voltage at cycle 2500 and 25° C. would be X+Y/2 and Z/2.

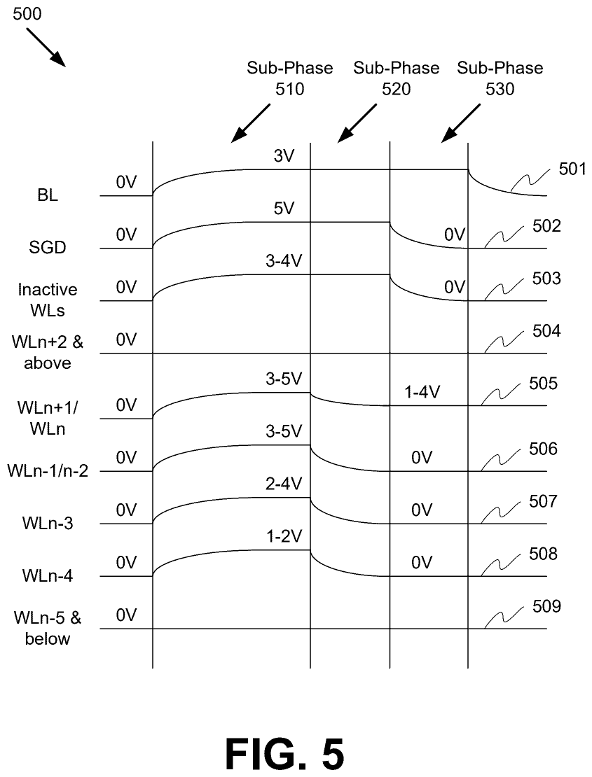

With continued reference to FIGS. 2A-2B, note FIG. 5 is a timing diagram 500 for operation of a memory device during a seeding phase of a program operation, in accordance with some embodiments. During a programming operation performed on a non-volatile memory device, such as memory device 130, certain phases can be encountered, including a seeding phase, which is typically followed by a program phase and a program verify phase. The seeding phase generally includes global boosting of channel voltages of inhibited strings in the memory device 130 in an attempt to counter-act program disturb resulting from the use of high voltage program pulses. During the subsequent phases, a pass voltage (Vpass) is applied to wordlines of the memory device 130 in order to further boost the channel voltage of the associated channel, and a program voltage is applied to selected wordlines (e.g., WLn) of the memory device 130, in order to program a certain level of charge to the selected memory cells on the wordlines representative of a desired value. In some embodiments, the amount of boost depends on the threshold voltage (Vt) of memory cells in the pillar that is being boosted. For example, if the threshold voltages of the memory cells are higher, the memory cells are boosted less, which may thus require higher pass voltages to boost.

Timing diagram 500 illustrates the various sub-phases of a seeding phase of a program operation, according to one embodiment. In this embodiment, different signals are applied to various devices in memory device 130 in each of the illustrated sub-phases. During sub-phase 510, program management component 113 causes a signal 501 having a seeding voltage (e.g., 3 volts) to be applied to the bitline 204 of the string 200, e.g., to raise the voltage of the pillar forming the vertical string 200 of memory cells connected to that pillar in 3D memory. In one embodiment, program management component 113 sends a signal to the wordline driver (or some other component) instructing that driver to apply signal 501 to the bitline 204. Signal 501 can remain at the seeding voltage throughout the seeding operation including all of sub-phases 510, 520, and 530. Following sub-phase 530, signal 501 returns to a ground voltage (e.g., 0V).

During sub-phase 510, program management component 113 further causes signal 502 to be applied to the drain select gate 230 and signal 503 (e.g., 3-4V) to be applied to one or more inactive wordlines (e.g., “dummy” wordlines coupled to devices in string 200 that are not used to store data). Signal 502 (e.g., 5V) activates the drain select gate 230 (e.g., turns it “on”) thereby allowing the seeding voltage to flow from bitline 204 through the drain select gate 230 to the various data wordlines connected to string 200. In one embodiment, the data wordlines include one or more wordlines connected to the remaining memory cell(s) 212 of string 200. These cells 212 are generally used for storing data, such as data from host system 120. Signal 502 and signal 503 remain high during sub-phase 520, and program management component 113 causes signal 502 and signal 503 to return to a ground voltage during sub-phase 530. Thus, signal 502 and signal 503 are ramped down after a delay period (e.g., equivalent to the length of sub-phase 520) relative to when other signals (e.g., signals 505-507) are ramped down. In one embodiment, the length of the delay period is sufficient to allow those other signals to settle to at least one of an intermediate voltage (e.g., 1-4V) or a ground voltage before signal 502 and signal 503 are ramped down.

In one embodiment, program management component 113 causes a signal 504 with a ground voltage (i.e., 0V) to be applied to certain wordlines of the string 200 during the seeding phase. For example, program management component 113 can cause signal 504 to be applied to wordlines (WLn+2) and above, which are above a selected wordline (WLn) in the string 200 throughout sub-phases 510, 520, and 530.

In one embodiment, program management component 113 can cause a positive voltage to be applied to certain wordlines of the string 200 during the seeding phase, where the positive voltage can be seen at the control gates 250 of the corresponding memory cells 212. The positive voltage can reduce electron barriers at those certain wordlines, allowing any residue electrons trapped on the source side to flow past the barriers and to the drain (i.e., bitline 204). As illustrated in timing diagram 500, during sub-phase 510 program management component 113 can cause a signal 505 with positive voltage (e.g., 3-5V) to be applied to a selected wordline (i.e., the wordline being programmed (WLn)) and at least one wordline (WLn+1) above the selected wordline in the string (i.e., a wordline located between WLn and the drain select gate 230). This positive voltage ensures that the channel potential is mainly determined by the seeding voltage (e.g., 3V). This higher channel potential leads to a larger drain induced barrier lowering (DIBL) effect on the adjacent source-side wordlines (i.e., the next wordlines lower down the string (WLn−1 and WLn−2)), allowing more residue electrons to flow to the drain side. During sub-phase 520, program management component 113 causes signal 505 to ramp down to an intermediate voltage (e.g. 1-4V). This intermediate voltage can be any voltage less than the high voltage applied during sub-phase 510 and a ground voltage. In addition, program management component 113 can cause a signal 506 with a positive voltage (e.g., 3-5V) to be applied to the adjacent source side wordlines (i.e., WLn−1 and WLn−2). This positive voltage can also reduce the electron barriers in these wordlines. During sub-phase 520, program management component 113 causes signal 506 to ramp down to the ground voltage (e.g. 0V). In one embodiment, program management component 113 can cause different voltages to be applied to WLn−1 and WLn−2. For example, a higher voltage can be applied on WLn−1 and a lower voltage can be applied on WLn−2 since WLn−1 receives more threshold voltage reduction due to the DIBL effect than WLn−2. In another embodiment, the same voltage could be applied to WLn−1 and WLn−2, as well.

In one embodiment, program management component 113 can cause a signal 507 with a positive voltage (e.g., 2-4V) to be applied to the next source side wordline (i.e., WLn−3) and a signal 508 with a positive voltage (e.g., 1-2V) to be applied to the next source side wordline (i.e., WLn−4). These positive voltages can also reduce the electron barriers in these wordlines. As illustrated, each subsequent voltage is lower than the previous voltage, such that the voltages step-down (i.e., get progressively closer to a ground voltage as the wordlines are further away from the selected wordline WLn) in order to smooth the potential gradient along the channel. During sub-phase 520, program management component 113 causes signal 507 and signal 508 to ramp down to the ground voltage (e.g. 0V). In one embodiment, program management component 113 causes a signal 509 with a ground voltage (i.e., 0V) to be applied to the remaining wordlines (WLn−5 and below) in string 200 and to source select gate 220 throughout sub-phases 510, 520, and 530. It should be understood that the specific voltage levels described herein are merely examples, and that in other embodiments, different voltage levels can be used. In another embodiment, when programming occurs from the source-side to the drain-side the orientation of the string as described above can be reversed such that the wordline voltages are stepped down as the wordlines are further away from the selected wordline WLn and towards the drain.

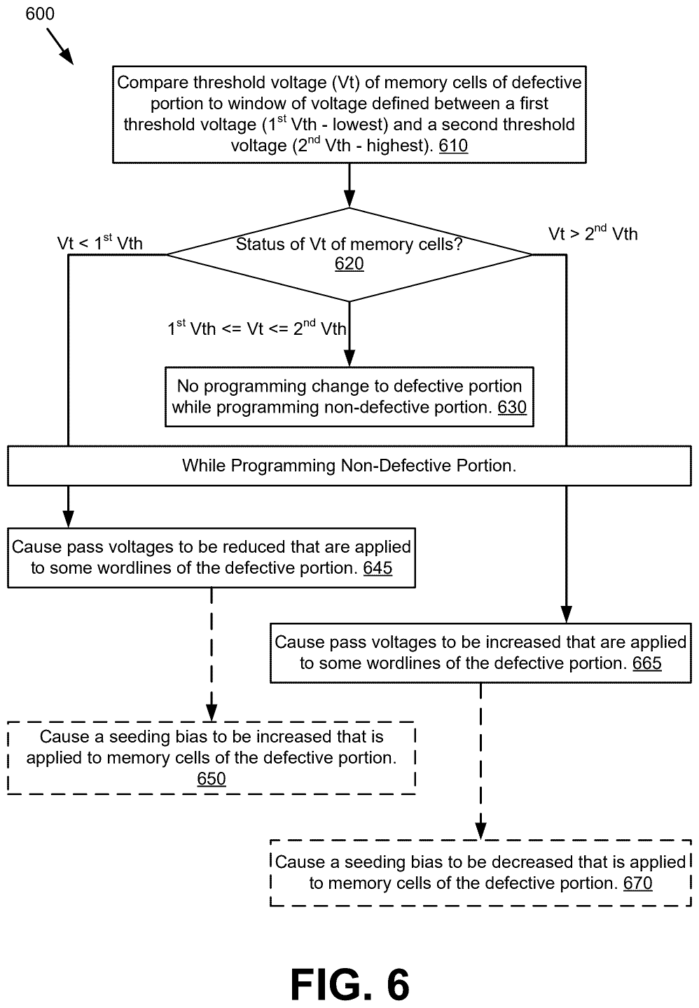

FIG. 6 is a flow diagram of an example method 600 of adjusting boost capability of a defective portion while programing a non-defective portion of a multi-deck memory device according to some embodiments. The method 600 can be performed by control logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 600 is performed by program management component 113 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Further to the discussion regarding boosting with reference to FIG. 5, the control logic may adapt specialization of programming and/or inhibit biasing conditions of the defective portion while programming the non-defective portion to account for modified boost capability of the defective portion (e.g., of one or more defective top decks). For example, if the defective portion is unable to be programmed, or the Vt distribution of the defective portion is quite different from standard random pattern of an incremental step pulse programming (ISPP) Vt distribution, the differing level of boost at the defective portion can result in some hot-electron or boosting-related issues. This can be compensated for by tuning seeding and inhibit biasing conditions when programming the initial WLs of the non-defective portion, as described in the below operations.

At operation 610, a threshold voltage of the memory cells is compared to threshold values. For example, the control logic (e.g., the program management component 113) compares the threshold voltage (Vt) of the memory cells of the defective portion to a window of voltage defined between a first threshold value (1^{st} Vth) and a second threshold value (2^{nd} Vth). In embodiments, the first threshold value may be understood as a lowest Vt of the voltage window and the second threshold value as a highest Vt of the voltage window.

At operation 620, a status of the threshold voltage is determined. For example, the control logic selects one of three paths depending on whether the threshold voltage fails to satisfy the first threshold value (e.g., is lower than the first threshold value), falls within the voltage window, or exceeds the second threshold value.

At operation 630, no change is made to programming the defective portion. For example, in response to the threshold voltage falling within the voltage window, the control logic makes no change to programming the defective portion while programming the non-defective portion. This means that the threshold voltages of the memory cell(s) are generally acceptable for favorable programming of the non-defective portion.

At operation 645, a pass voltage on wordlines of the defective portion is reduced. For example, in response to the threshold voltage failing to satisfy the first threshold value, the control logic causes, while programming the non-defective portion, pass voltages to be reduced that are applied to some wordlines of the defective portion. This reduction in voltage may be incremental, for example, some low voltage such as 0.25V, 0.5V, 0.7V, or other voltage below 1V. The pass voltage reduction can also be applied to wordlines targeted for a regular program-verify operation and/or a related read operation, for example.

At operation 650, a seeding bias voltage applied to some wordlines of the memory cells is increased, e.g., a seeding WL voltage is applied before the pass WL voltage. For example, the control logic may also optionally cause (in addition to operation 645), while programming the non-defective portion, a seeding bias voltage to be increased that is applied to the wordlines of memory cells of the defective portion. This seeding bias volage may be a bias voltage applied to the seeding voltage during the seeding phase of programming (see FIG. 5). This seeding bias voltage may also be incremented in small steps such as was applied to adjusting the pass voltage (see operation 645).

At operation 665, a pass voltage on wordlines of the defective portion is increased. For example, in response to the threshold voltage of memory cells of the defective portion exceeding a threshold value, the control logic causes, while programming the non-defective portion, pass voltages to be increased that are applied to some wordlines of the defective portion. This increase in voltage may be incremental, for example, some low voltage such as 0.25V, 0.5V, 0.7V, or other voltage below 1V. The pass voltage reduction can also be applied to wordlines targeted for a regular program-verify operation and/or a related read operation, for example.

At operation 670, a seeding bias voltage applied to some wordlines of the memory cells is decreased, e.g., a seeding WL voltage is applied before the pass WL voltage. For example, the control logic may also optionally cause (in addition to operation 665), while programming the non-defective portion, a seeding bias voltage to be decreased that is applied to wordlines of memory cells of the defective portion. This seeding bias voltage may also be incremented in small steps such as was applied to adjusting the pass voltage (see operation 665).

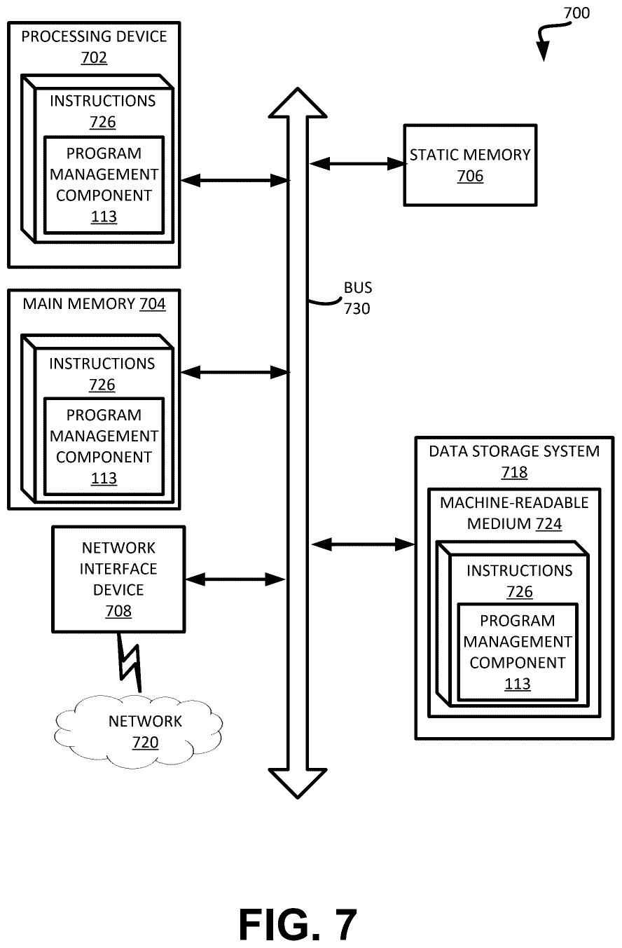

FIG. 7 illustrates an example machine of a computer system 700 within which a set of instructions, for causing the machine to perform any one or more of the methodologies discussed herein, can be executed. In some embodiments, the computer system 700 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the program management component 113 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a data storage system 718, which communicate with each other via a bus 730.

Processing device 702 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 702 can also be one or more special-purpose processing devices such as an application specific integrated circuit (ASIC), a field programmable gate array (FPGA), a digital signal processor (DSP), network processor, or the like. The processing device 702 is configured to execute instructions 726 for performing the operations and steps discussed herein. The computer system 700 can further include a network interface device 708 to communicate over the network 720.

The data storage system 718 can include a machine-readable storage medium 724 (also known as a computer-readable medium, such as a non-transitory computer-readable medium) on which is stored one or more sets of instructions 726 or software embodying any one or more of the methodologies or functions described herein. The instructions 726 can also reside, completely or at least partially, within the main memory 704 and/or within the processing device 702 during execution thereof by the computer system 700, the main memory 704 and the processing device 702 also constituting machine-readable storage media. The machine-readable storage medium 724, data storage system 718, and/or main memory 704 can correspond to the memory sub-system 110 of FIG. 1A.

In one embodiment, the instructions 726 include instructions to implement functionality corresponding to the program management component 113 of FIG. 1A). While the machine-readable storage medium 724 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a three-dimensional (3D) memory array comprising a plurality of blocks; and
control logic coupled to the 3D memory array, the control logic to perform operations comprising:
identifying a defective portion of a block of the plurality of blocks, wherein the defective portion is located above a non-defective portion of the block;
causing the defective portion to be pre-programmed before programming the non-defective portion; and
while pre-programming the defective portion:
causing a first voltage to be applied to a top plurality of wordlines of the defective portion; and
causing a second voltage to be applied to a bottom plurality of wordlines of the defective portion that are located below the top plurality of wordlines, wherein the second voltage is lower than the first voltage.

2. The memory device of claim 1, wherein the operations further comprise one of:
causing to be supplied, from two voltage sources, the first voltage and second voltage in a single pulse; or
causing to be supplied, from a single voltage source, the first voltage in a first pulse and the second voltage in a second pulse.

3. The memory device of claim 1, wherein the operations further comprise:
identifying one or more wordlines of the defective portion that are defective; and
one of causing a voltage driver of the one or more wordlines to be turned off or routing the one or more wordlines to a pass voltage.

4. The memory device of claim 3, wherein the operations further comprise reducing the pass voltage compared to a pass voltage used on unprogrammed wordlines of the non-defective portion.

5. The memory device of claim 1, wherein the operations further comprise causing a pre-program verify operation to be performed on the defective portion to minimize a threshold voltage of programmed cells of the defective portion.

6. The memory device of claim 5, wherein the operations further comprise adjusting a voltage of a pre-program pulse during the pre-programming to target the minimized threshold voltage based on a number of program-erase cycles of the defective portion and on a current temperature of the 3D memory array.

7. The memory device of claim 1, wherein the operations further comprise adjusting a voltage of a pre-program pulse to ensure pre-programming of the defective portion completes in a single pulse, wherein the adjusting is based on at least one of a number of program-erase cycles of the defective portion or a current temperature of the 3D memory array.

8. The memory device of claim 1, wherein the operations further comprise:
causing the defective portion to be erased before pre-programming the defective portion; and
while erasing the defective portion:
causing a first voltage offset to be applied to the top plurality of wordlines; and
causing a second voltage offset to be applied to the bottom plurality of wordlines of the defective portion, wherein the first voltage offset is lower than the second voltage offset.

9. The memory device of claim 1, wherein the operations further comprise:
determining that a threshold voltage of memory cells of the defective portion fail to satisfy a threshold value; and
while programming the non-defective portion, at least one of:
causing pass voltages to be reduced that are applied to some wordlines of the defective portion; or
causing a seeding bias voltage to be increased that is applied to some wordlines of memory cells of the defective portion.

10. A method comprising:
identifying, by control logic of a memory device comprising a three-dimensional (3D) memory array, a defective portion of a block of the 3D memory array, wherein the defective portion is located above a non-defective portion of the block;
causing the defective portion to be pre-programmed before programming the non-defective portion; and
while pre-programming the defective portion:
causing, by the control logic, a first voltage to be applied to a top plurality of wordlines of the defective portion; and
causing, by the control logic, a second voltage to be applied to a bottom plurality of wordlines of the defective portion that are located below the top plurality of wordlines, wherein the second voltage is lower than the first voltage.

11. The method of claim 10, further comprise comprising:
supplying, from two voltage sources, the first voltage and second voltage in a single pulse; or
supplying, from a single voltage source, the first voltage in a first pulse and the second voltage in a second pulse.

12. The method of claim 10, further comprising:
identifying one or more wordlines of the defective portion that are defective; and
one of causing a voltage driver of the one or more wordlines to be turned off or routing the one or more wordlines to a pass voltage.

13. The method of claim 12, further comprising reducing the pass voltage compared to a pass voltage used on unprogrammed wordlines of the non-defective portion.

14. The method of claim 10, further comprising causing a pre-program verify operation to be performed on the defective portion to minimize a threshold voltage of programmed cells of the defective portion.

15. The method of claim 14, further comprising adjusting a voltage of a pre-program pulse during the pre-programming to target the minimized threshold voltage based on a number of program-erase cycles of the defective portion and on a current temperature of the 3D memory array.

16. The method of claim 10, further comprising adjusting a voltage of a pre-program pulse to ensure pre-programming of the defective portion completes in a single pulse, wherein the adjusting is based on at least one of a number of program-erase cycles of the defective portion or a current temperature of the 3D memory array.

17. The method of claim 10, further comprising:
causing the defective portion to be erased before pre-programming the defective portion; and
while erasing the defective portion:
causing a first voltage offset to be applied to the top plurality of wordlines; and
causing a second voltage offset to be applied to the bottom plurality of wordlines of the defective portion, wherein the first voltage offset is lower than the second voltage offset.

18. The method of claim 10, further comprising:
determining that a threshold voltage of memory cells of the defective portion exceed a threshold value; and
while programming the non-defective portion, at least one of:
causing pass voltages to be increased that are applied to some wordlines of the defective portion; or
causing a seeding bias voltage to be decreased that is applied to some wordlines of memory cells of the defective portion.

19. A method comprising:
identifying, by control logic of a memory device comprising a three-dimensional (3D) memory array, a defective portion of a block of the 3D memory array, wherein the defective portion is located above a non-defective portion of the block;
causing the defective portion to be erased before pre-programming the defective portion;
causing, by the control logic while erasing the defective portion, a first voltage offset to be applied to a top plurality of wordlines; and
causing, by the control logic while erasing the defective portion, a second voltage offset to be applied to a bottom plurality of wordlines of the defective portion that are located below the top plurality of wordlines, wherein the first voltage offset is lower than the second voltage offset.

20. The method of claim 19, further comprising, while pre-programming the defective portion:
causing a first voltage to be applied to the top plurality of wordlines of the defective portion; and
causing a second voltage to be applied to the bottom plurality of wordlines of the defective portion, wherein the second voltage is lower than the first voltage.
